(19) United States
(12) Patent Application Publication
(10) Pub. No.: US 2025/0275324 A1
(43) Pub. Date: Aug. 28, 2025

(54) DISPLAY DEVICE IN WHICH PAD ELECTRODES OF A CIRCUIT BOARD AND PAD ELECTRODES OF A DISPLAY PANEL ARE ALIGNED AND A METHOD FOR FABRICATING THE SAME

(71) Applicant: SAMSUNG DISPLAY CO., LTD., YONGIN-SI (KR)

(72) Inventor: Ahn Ho JEE, Yongin-si (KR)

(21) Appl. No.: 18/954,684

(22) Filed: Nov. 21, 2024

(30) Foreign Application Priority Data
Feb. 26, 2024 (KR) 10-2024-0027487

(51) Int. Cl. H01L 33/62

(52) U.S. Cl. CPC H10H 20/857; H10H 20/0364; H10H 20/0365

(57) ABSTRACT

A display device includes: a display panel; and a circuit board connected to the display panel, wherein the circuit board includes a plurality of sub-bonding portions that are separated from each by a plurality of slits, and a length of each of the plurality of sub-bonding portions is set based on an elongation rate of the circuit board.

### CROSS-REFERENCE TO RELATED APPLICATION

This application claims priority under 35 U.S.C. §119 to Korean Patent Application No. 10-2024-0027487, filed on Feb. 26, 2024 in the Korean Intellectual Property Office, the disclosure of which is incorporated by reference herein in its entirety.

### TECHNICAL FIELD

Embodiments of the present invention relates to a display device, and more particularly, to a display device in which pad electrodes of a circuit board and pad electrodes of a display panel are aligned, and a method for fabricating the same.

### DISCUSSION OF THE RELATED ART

Recently, flat panel display devices such as organic light emitting diode display devices have been widely used in various electronic devices such as televisions, laptop computers, and smart phones.

In many cases, a flat display device generally includes a display panel including a substrate made of glass, and a flexible circuit board may be connected to the display panel.

### SUMMARY

According to an embodiment of the present invention, a display device includes: a display panel; and a circuit board connected to the display panel, wherein the circuit board includes a plurality of sub-bonding portions that are separated from each by a plurality of slits, and a length of each of the plurality of sub-bonding portions is set based on an elongation rate of the circuit board.

In an embodiment of the present invention, the length of the sub-bonding portion is calculated by a following equation: C=B/A, where A is an elongation rate of the sub-bonding portion per unit length, B is a maximum elongation amount of the sub-bonding portion, and C is the length of the sub-bonding portion.

In an embodiment of the present invention, B is set within 50% of a pitch of an outermost pad electrode of a plurality of pad electrodes that are disposed on the sub-bonding portion.

In an embodiment of the present invention, the circuit board includes: an insulating layer; a pad electrode disposed on the insulating layer; a base layer disposed on the pad electrode; an adhesive layer disposed on the base layer; and a cover layer disposed on the adhesive layer.

In an embodiment of the present invention, the base layer includes the plurality of slits.

In an embodiment of the present invention, the base layer includes the plurality of slits in a bonding area of the circuit board.

In an embodiment of the present invention, the plurality of slits are arranged in the base layer along a first direction, each of the plurality of slits extends in a second direction, and the first direction and the second direction cross each other.

In an embodiment of the present invention, the base layer includes a polyimide.

In an embodiment of the present invention, the insulating layer includes a same material as the base layer.

In an embodiment of the present invention, the display device further includes an anisotropic conductive film disposed between the display panel and the circuit board.

In an embodiment of the present invention, the insulating layer is disposed in a non-bonding area of the circuit board.

In an embodiment of the present invention, the pad electrode is disposed in a non-bonding area and a bonding area of the circuit board.

In an embodiment of the present invention, the base layer is disposed in a non-bonding area and a bonding area of the circuit board.

In an embodiment of the present invention, the adhesive layer is disposed in a non-bonding area and a bonding area of the circuit board.

In an embodiment of the present invention, the cover layer is disposed in a non-bonding area and a bonding area of the circuit board.

In an embodiment of the present invention, the pad electrode of the circuit board is connected to a pad electrode of the display panel.

In an embodiment of the present invention, the pad electrode of the circuit board is connected to the pad electrode of the display panel in a bonding area of the circuit board.

According to an embodiment of the present invention, a method for fabricating a display device includes: disposing an anisotropic conductive film on a substrate of a display panel; disposing a circuit board on the anisotropic conductive film, wherein the circuit board includes a plurality of sub-bonding portions that are separated from each other by a plurality of slits; disposing a heat conduction sheet on the circuit board; disposing a heating/pressurizing header on the heat conduction sheet; and connecting a pad electrode of the circuit board and a pad electrode that is disposed on the substrate to each other by pressurizing and heating the heat conduction sheet with the heating/pressurizing header, wherein a length of each of the plurality of sub-bonding portions is set based on an elongation rate of the circuit board.

In an embodiment of the present invention, the length of the sub-bonding portion is calculated by a following equation: C=B/A, where A is an elongation rate of the sub-bonding portion per unit length, B is a maximum elongation amount of the sub-bonding portion, and C is the length of the sub-bonding portion.

In an embodiment of the present invention, B is set within 50% of a pitch of an outermost pad electrode of a plurality of pad electrodes that are disposed on the sub-bonding portion, wherein the plurality of pad electrodes includes the pad electrode of the circuit board.

### BRIEF DESCRIPTION OF THE DRAWINGS

The above and other aspects and features of the present invention will become more apparent by describing in detail embodiments thereof with reference to the attached drawings, in which:

FIG. 1 is a perspective view of a display device according to an embodiment of the present invention;

FIG. 2 is an exploded perspective view of a circuit board according to an embodiment of the present invention;

FIG. 3 is a cross-sectional view taken along line X1-X1′ of FIG. 2;

FIG. 4 is a cross-sectional view taken along line X2-X2′ of FIG. 2;

FIG. 5 is a cross-sectional view taken along line X3-X3′ of FIG. 2; and

FIGS. 6, 7 and 8 are cross-sectional views for describing processes of a method for fabricating the display device according to an embodiment of the present invention.

### DETAILED DESCRIPTION OF THE EMBODIMENTS

Features of the present invention and methods to achieve them will become apparent from the descriptions of embodiments hereinbelow with reference to the accompanying drawings. However, the present invention is not limited to embodiments disclosed herein but may be implemented in various different ways.

As used herein, a phrase “an element A on an element B” refers to that the element A may be disposed directly on the element B and/or the element A may be disposed indirectly on the element B with another element C interposed therebetween. Like reference numerals may denote like elements throughout the specification and drawings. The figures, dimensions, ratios, angles, numbers of elements given in the drawings are merely illustrative and are not limiting.

It will be understood that, although the terms “first,” “second,” etc. may be used herein to describe various elements, these elements should not be limited by these terms. These terms are only used to distinguish one element from another element. For instance, a first element discussed below could be termed a second element without departing from the spirit and scope of the present invention. Similarly, the second element could also be termed the first element.

Features of each of various embodiments of the present invention may be partially or entirely combined with each other and may technically variously interwork with each other, and respective embodiments may be implemented independently of each other or may be implemented together in association with each other.

Hereinafter, embodiments of the present invention will be described with reference to the accompanying drawings.

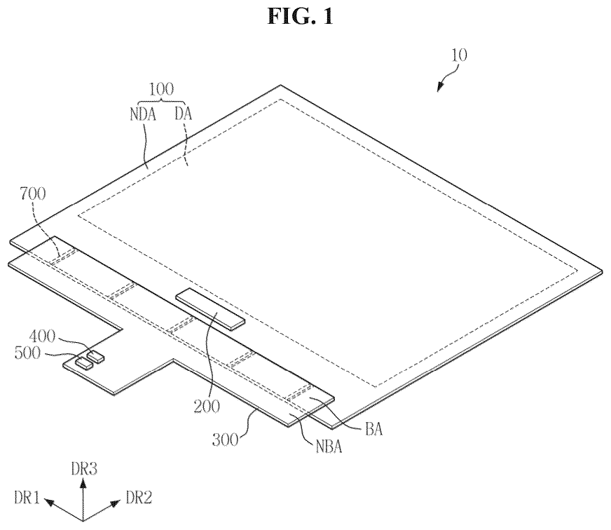

FIG. 1 is a perspective view of a display device according to an embodiment of the present invention.

Referring to FIG. 1, a display device 10 may be applied to portable electronic devices such as mobile phones, smartphones, tablet personal computers (PCs), mobile communication terminals, electronic notebooks, electronic books, portable multimedia players (PMPs), navigation devices, and ultra mobile PCs (UMPCs). As an example, the display device 10 may be applied as a display unit of televisions, laptop computers, monitors, billboards, or the Internet of Things (IOTs). As another example, the display device 10 may be applied to wearable devices such as smart watches, watch phones, glasses-type displays, and head mounted displays (HMDs).

The display device 10 may have a shape similar to a rectangular shape in a plan view. For example, the display device 10 may have a shape similar to a rectangular shape, in plan view, having long sides in a first direction DR1 and short sides in a second direction DR2. A corner where the long side in the first direction DR1 and the short side in the second direction DR2 meet may be rounded with a predetermined radius of curvature or may be a right-angle. The shape of the display device 10 in a plan view is not limited to the rectangular shape, and may be a shape similar to other polygonal shapes, a circular shape, or an elliptical shape.

The display device 10 may include a display panel 100, a display driver 200, a circuit board 300, a touch driver 400, and a power supply unit 500.

The display panel 100 may include a display area DA and a non-display area NDA.

The display area DA may include a plurality of pixels disposed therein for displaying an image. The display area DA may emit light from a plurality of emission areas or a plurality of opening areas. For example, the display panel 100 may include pixel circuits including switching elements, a pixel defining film defining the emission areas or the opening areas, and self-light emitting elements.

The non-display area NDA may be disposed around and/or adjacent to the display area DA. The non-display area NDA may be an area outside the display area DA. For example, the non-display area NDA may be an edge area of the display area DA of the display panel 100. The non-display area NDA may include a gate driver disposed therein supplying gate signals to gate lines, and fan-out lines connecting the display driver 200 and the display area DA to each other. The non-display area NDA may include the display driver 200 and pad portions connected to the circuit board 300.

The display driver 200 may output signals and voltages for driving the display panel 100. The display driver 200 may supply data voltages to data lines. The display driver 200 may supply source voltages to power lines and supply gate control signals to the gate driver. The display driver 200 may be formed as an integrated circuit (IC) and mounted on the display panel 100 in a chip on glass (COG) manner, a chip on plastic (COP) manner, or an ultrasonic bonding manner. As an example, the display driver 200 may be disposed in the non-display area NDA. As another example, the display driver 200 may be mounted on the circuit board 300.

The circuit board 300 may be attached onto the pad portions of the display panel 100 using an anisotropic conductive film (ACF). Lead lines of the circuit board 300 may be electrically connected to the pad portions of the display panel 100. The circuit board 300 may be a flexible printed circuit board, a flexible printed circuit, a printed circuit board, or a flexible film such as a chip on film.

The circuit board 300 may include a plurality of slits 700. For example, the circuit board 300 may include a bonding area that overlaps the pad portions of the display panel 100 and a non-bonding area that does not overlap the pad portions of the display panel 100, and the plurality of slits 700 may be disposed in the bonding area BA of the circuit board 300. In a plan view, each slit 700 may have a shape that extends along the second direction DR2. In a plan view, the plurality of slits 700 may be arranged along the first direction DR1. Here, the first direction DR1 may correspond to, for example, an elongation direction of the circuit board 300. The slit 700 may control an elongation rate of the circuit board 300. For example, the slit 700 may control an elongation rate of the circuit board 300 in the first direction DR1. To this end, according to an embodiment of the present invention, the slit 700 may extend along a direction (e.g., the second direction DR2) crossing the elongation direction (e.g., the first direction DR1) of the circuit board 300. Pressure is applied to the circuit board 300 during a process of attaching the circuit board 300 and the display panel 100 to each other, and the circuit board 300 may be elongated (or expanded) along the first direction DR1 by such pressure. Since the display panel 100 is made of a material that is harder than the circuit board 300, the circuit board 300 may be elongated by the pressure described above, while the display panel 100 might not elongated by the pressure described above, such that a problem that pad electrodes of the circuit board 300 and pad electrodes of the display panel 100 are not in contact with each other may occur. An elongation amount (or an elongation degree) of the circuit board 300 tends to be gradually accumulated and increased along the first direction DR1 or a direction reverse (or opposite) to the first direction DR1 (hereinafter referred to as a first reverse direction) from a central portion of the circuit board 300. Accordingly, the circuit board 300 may have a greater elongation amount on both side surfaces thereof than at the central portion thereof. The slit 700 may have a shape in which it cuts a portion of the circuit board 300 in the direction crossing the first direction to prevent the elongation amount from being accumulated in the first direction. An example in which five slits 700 are arranged in the bonding area BA has been illustrated in FIG. 1, but this is only an example, and the number of slits 700 described above is not limited thereto and may be variously changed.

The touch driver 400 may be mounted on the circuit board 300. The touch driver 400 may be electrically connected to a touch sensing unit of the display panel 100. The touch driver 400 may supply touch driving signals to a plurality of touch electrodes of the touch sensing unit and sense change in capacitance between the plurality of touch electrodes. For example, the touch driving signal may be a pulse signal having a predetermined frequency. The touch driver 400 may decide whether or not an input has occurred and calculate input coordinates, based on the change in capacitance between the plurality of touch electrodes. The touch driver 400 may be formed as an integrated circuit (IC).

The power supply unit 500 may be disposed on the circuit board 300 and may supply source voltages to the display driver 200 and the display panel 100. The power supply unit 500 may generate a driving voltage and supply the driving voltage to a driving voltage line, may generate an initialization voltage and supply the initialization voltage to an initialization voltage line, may generate a reference voltage and supply the reference voltage to a reference voltage line, and may generate a common voltage and supply the common voltage to a common voltage line. In this case, the common voltage of the common voltage line may be supplied to a common electrode of light emitting elements ED of the plurality of pixels. The driving voltage may be a high potential voltage for driving the light emitting element ED, and the common voltage may be a low potential voltage for driving the light emitting element ED.

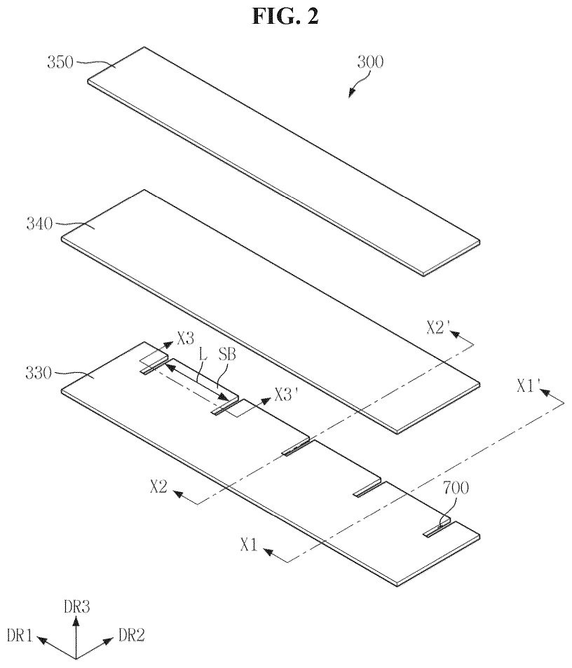

FIG. 2 is an exploded perspective view of a circuit board 300 according to an embodiment

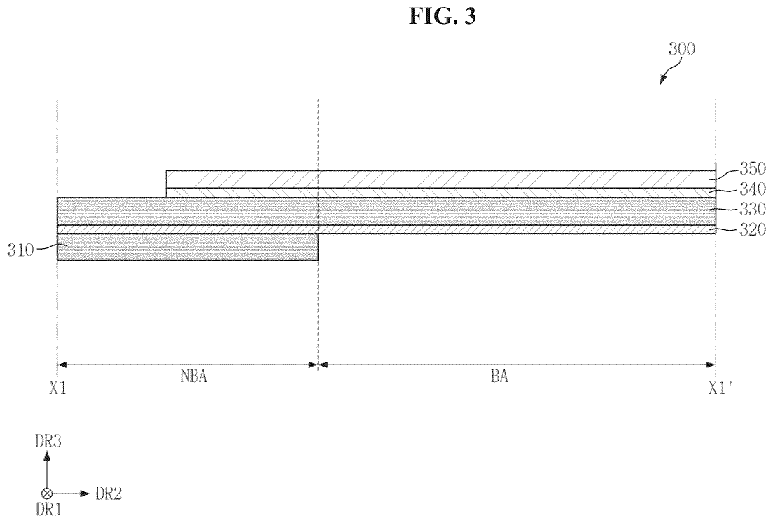

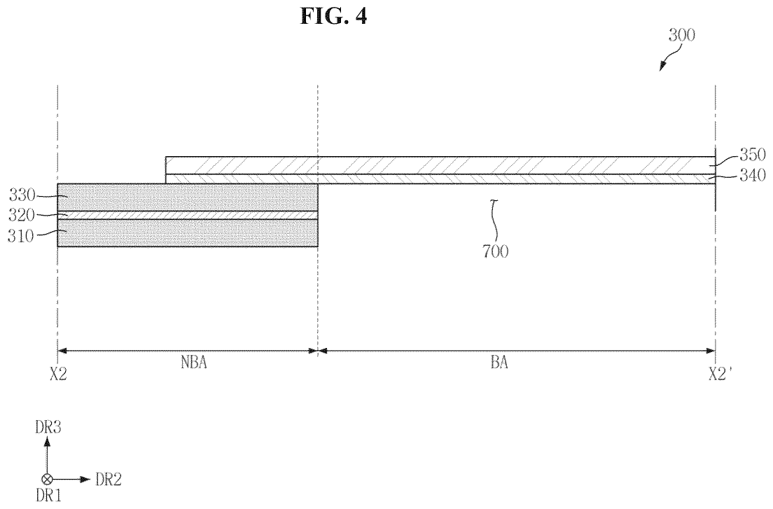

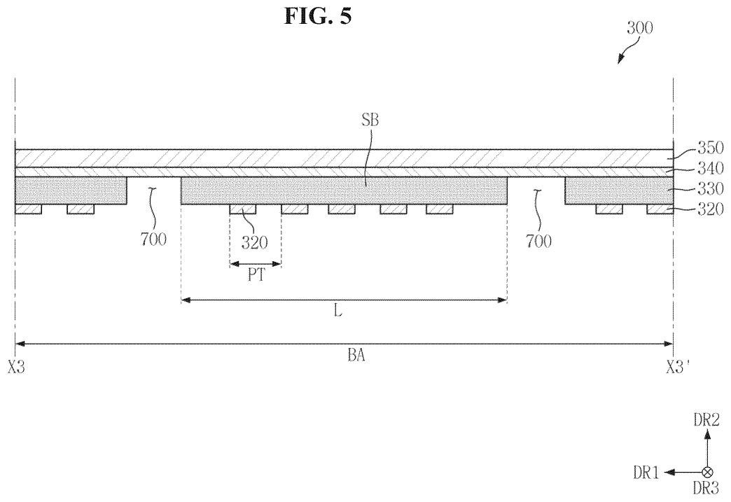

of the present invention, FIG. 3 is a cross-sectional view taken along line X1-X1′ of FIG. 2, FIG. 4 is a cross-sectional view taken along line X2-X2′ of FIG. 2, and FIG. 5 is a cross-sectional view taken along line X3-X3′ of FIG. 2. For example, FIG. 2 may be an exploded perspective view of the circuit board 300 of FIG. 1 described above.

The circuit board 300 may include an insulating layer 310, pad electrodes 320, a base layer 330, an adhesive layer 340, and a cover layer 350 as in an example that is illustrated in FIGS. 2 to 5.

The insulating layer 310 may be disposed in the non-bonding area NBA. The insulating layer 310 may include a polyimide.

The pad electrodes 320 may be disposed on the insulating layer 310. For example, the pad electrodes 320 may be disposed on the insulating layer 310 in the non-bonding area NBA and may be disposed in the bonding area BA. In this case, the pad electrodes 320 may be covered by the insulating layer 310 in the non-bonding area NBA. The pad electrode 320 may include a metal. The circuit board 300 and the pad portions of the display panel 100 may be electrically connected to each other through the pad electrodes 320.

The base layer 330 may be disposed on the pad electrodes 320. For example, the base layer 330 may be disposed on the pad electrodes 320 in the non-bonding area NBA and the bonding area BA. In this case, the base layer 330 may cover the pad electrodes 320 in the non-bonding area NBA and the bonding area BA. The base layer 330 may be made of the same material as the insulating layer 310 described above. For example, the base layer 330 may include a polyimide.

The adhesive layer 340 may be disposed on the base layer 330. For example, the adhesive layer 340 may be disposed on the base layer 330 in the non-bonding area NBA and the bonding area BA. In this case, the adhesive layer 340 may overlap a portion of the base layer 330 in the non-bonding area NBA. The adhesive layer 340 may be disposed between the base layer 330 and a cover layer 350 to be described later and may adhere the base layer 330 and the cover layer 350 to each other.

The cover layer 350 may be disposed on the adhesive layer 340. For example, the cover layer 350 may be disposed on the adhesive layer 340 in the non-bonding area NBA and the bonding area BA. For example, the cover layer 350 may cover an entirety of adhesive layer 340. In this case, the cover layer 350 may overlap a portion of the base layer 330 in the non-bonding area NBA. The cover layer 350 may be a reinforcing layer capable of supporting the circuit board 300 that is flexible.

As in an example illustrated in FIGS. 2, 4, and 5, the slit 700 may be formed in the base layer 330. For example, the plurality of slits 700 may be disposed in the bonding area BA of the base layer 330. In a plan view, each slit 700 may have a shape in which it extends along the second direction DR2. In a plan view, the plurality of slits 700 may be arranged along the first direction DR1. Here, the first direction DR1 may correspond to, for example, an elongation direction of the base layer 330 that is provided in the circuit board 300.

According to an embodiment of the present invention, as illustrated in FIGS. 2 and 5, the base layer 330 may include a plurality of sub-bonding portions SB that are divided by the plurality of slits 700 in the bonding area BA. The plurality of sub-bonding portions SB may be disposed in the bonding area BA.

Depending on the elongation rate of the circuit board 300, a predetermined length L of the sub-bonding portion SB (or a distance between adjacent slits 700) for connecting the circuit board 300 and the display panel 100 to each other may be changed.

The length L of the sub-bonding portion SB (or the distance between the adjacent slits 700) may be determined by the following equation.

When the length L of any one sub-bonding portion SB is defined as “C”, a maximum elongation amount of any one sub-bonding portion SB is defined as “B”, and an elongation rate of any one sub-bonding portion SB per unit length is defined as “A”, the length of the sub-bonding portion SB (or the distance between the adjacent slits 700) described above may be determined by the following equation:

C=B/A.

Here, A may refer to an elongation rate of the circuit board 300 per unit length. For example, A may refer to an elongation rate of the base layer 330, which is included in the circuit board 300, per unit length. The elongation rate of the base layer 330 per unit length is a unique numerical value that is determined depending on material properties or the like of the base layer 330, and is a numerical value known in advance.

B is the maximum elongation amount, which may be related to an overlap ratio between an outermost pad electrode 320 (hereinafter referred to as a first outermost pad electrode 320) of the circuit board 300 and an outermost pad electrode (hereinafter a second outermost pad electrode) of the display panel 100 that corresponds to the first outermost pad electrode 320. Here, the first outermost pad electrode 320 may refer to a pad electrode 320 disposed on the outermost portion of one side of the sub-bonding portion SB among a plurality of pad electrodes 320 disposed on the sub-bonding portion SB. According to an embodiment of the present invention, B may be smaller than or equal to 50 (or 50%). For example, B may be set within 50% of a pitch PT of the first outermost pad electrode 320. However, a numerical value of B is not limited thereto, and may be variously changed.

An example of calculating the length of the sub-bonding portion SB (e.g., the distance between the adjacent slits 700) described above will be described in detail below.

For example, when the elongation rate A of the base layer 330 (e.g., polyimide) of the circuit board 300 per unit length is 1 μm/1 mm and the maximum elongation amount B is 50, the length C of the sub-bonding portion SB of the circuit board 300 may be 50 mm. For example, the distance between the adjacent slits 700 of the circuit board 300 may be 50 mm. Here, the maximum elongation amount B may be set as an occupancy ratio of the pad electrode 320 when the pitch PT (e.g., a cycle) of the first outermost pad electrode 320 is 100 and an occupancy ratio and a non-occupancy ratio of the pad electrode 320 at the pitch PT of 100 are 50:50, as in the example illustrated in FIG. 5.

According to an embodiment of the present invention, the respective sub-bonding portions SB of the circuit board 300 may have the same length as each other. For example, the plurality of slits 700 may be disposed at equal intervals. For example, each sub-bonding portion SB may have a length of about 50 mm.

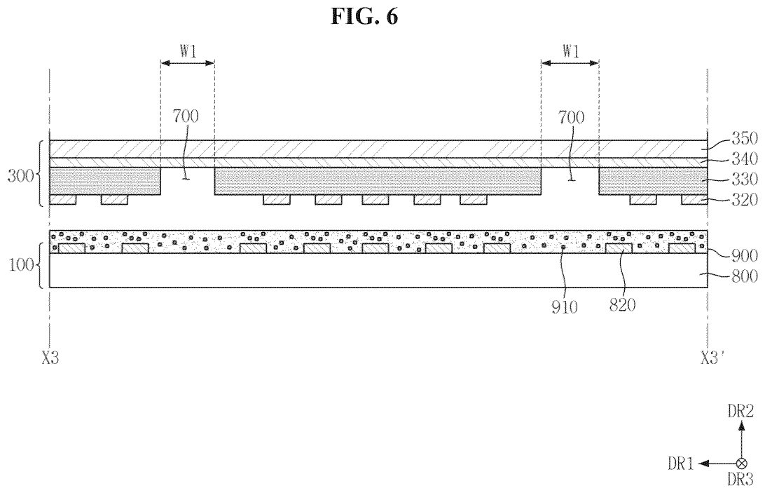

FIGS. 6 to 8 are cross-sectional views for describing processes of a method for fabricating the display device according to an embodiment of the present invention.

First, as illustrated in FIG. 6, a substrate 800 of a display panel 100 on which pad electrodes 820 are disposed is prepared, and an anisotropic conductive film 900 including a plurality of conductive particles 910 may be disposed on the pad electrode 820 and the substrate 800. Thereafter, the circuit board 300 having the plurality of slits 700 described above may be disposed on the anisotropic conductive film 900.

According to an embodiment of the present invention, in consideration of elongation of the circuit board 300 during a pressurizing process to be described later, an interval between the pad electrodes 320 (hereinafter referred to as first pad electrodes 320) of the circuit board 300 may be different from an interval that is between the pad electrodes 820 (hereinafter referred to as second pad electrodes 820) of the display panel 100. For example, the interval that is between the first pad electrodes 320 may be smaller than the interval that is between the second pad electrodes 820.

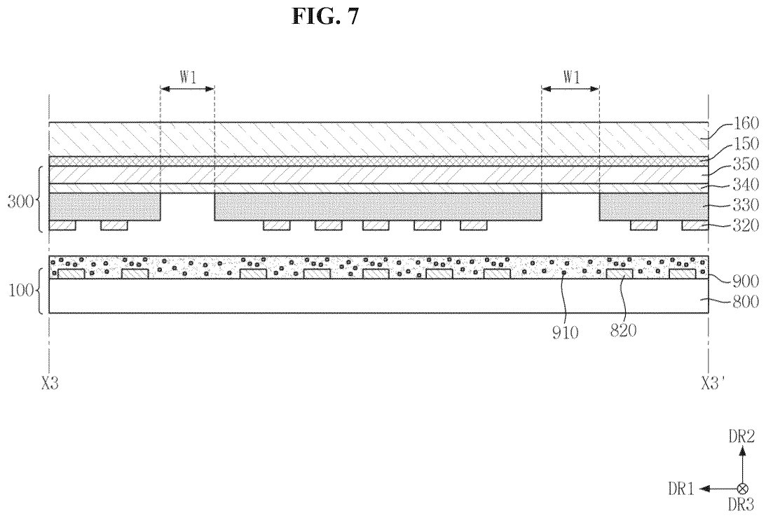

Next, as illustrated in FIG. 7, a heating/pressurizing header 160 may be disposed on the circuit board 300. According to an embodiment of the present invention, a heat conduction sheet 150 may be disposed between the circuit board 300 and the heating/pressurizing header 160. The heat conduction sheet 150 may evenly transfer heat and pressure of the heating/pressurizing header 160 to the circuit board 300 that is located below the heat conduction sheet 150. For example, the heat conduction sheet 150 may include a Teflon™ material.

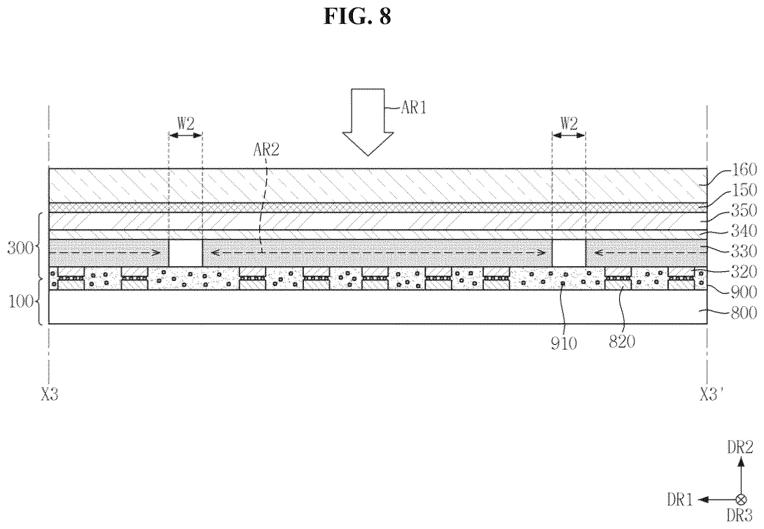

Next, as illustrated in FIG. 8, the heating/pressurizing header 160 may descend along a direction of an arrow ARI to pressurize the circuit board 300. For example, the heating/pressurizing header 160 may cure the anisotropic conductive film 900 that is disposed between the circuit board 300 and the substrate 800 of the display panel 100 by heating and pressurizing the heat conduction sheet 150. In addition, in such a pressurizing process, the first pad electrodes 320 and the second pad electrodes 820, which correspond to each other, may be electrically connected to each other by the conductive particles 910 that are disposed between the first pad electrodes 320 and the second pad electrodes 820. In this case, the base layer 330 of the circuit board 300 may be elongated (or expanded) in directions (e.g., directions of a dotted line arrow AR2 or the first direction DR1 and the first reverse direction) perpendicular to a pressurizing direction (e.g., a direction reverse to a third direction DR3 or the direction of the arrow AR1) by the pressure through the heating/pressurizing header 160.

Due to the elongation of the base layer 330, the interval between the first pad electrodes 320 that are disposed on the base layer 330 increases, such that the first pad electrodes 320 and the second pad electrodes 820 may be aligned with each other. In other words, due to the elongation of the base layer 330, the first pad electrodes 320 and the second pad electrodes 820 corresponding to each other may be disposed to overlap each other. In addition, a width of the slit 700 of the base layer 330 may be reduced due to the elongation of the base layer 330. For example, referring to FIGS. 6 and 8, a width W2 of the slit 700 of the base layer 330 after being elongated may be smaller than a width W1 of the slit 700 of the base layer 330 before the elongation of the base layer 330. In other words, each of the sub-bonding portions SB of the base layer 330 is elongated due to the elongation of the base layer 330, and accordingly, a distance between adjacent sub-bonding portions SB (e.g., the width of the slit) may be reduced.

With the display device according to an embodiment of the present invention, the base layer 330 of the circuit board 300 includes the plurality of slits 700, and accordingly, the elongation amount of the circuit board 300 may be reduced. Accordingly, alignment accuracy between the pad electrodes 320 of the circuit board 300 and the pad electrodes 820 of the display panel 100 that correspond to the pad electrodes 320 may be increased.

In addition, with the display device according to an embodiment of the present invention, an accurate length of the sub-bonding portion SB (or an accurate distance between the adjacent slits 700) may be calculated based on the elongation rate of the base layer 330, and thus, the alignment accuracy between the pad electrodes 320 of the circuit board 300 and the pad electrodes 820 of the display panel 100 that corresponds to the pad electrodes 320 may be further increased.

While the present invention has been described with reference to the embodiments thereof, it will be understood by those of ordinary skill in the art that various changes in form and detail may be made thereto without departing from the spirit and scope of the present invention.

What is claimed is:

1. A display device comprising:
a display panel; and
a circuit board connected to the display panel,
wherein the circuit board includes a plurality of sub-bonding portions that are separated from each by a plurality of slits, and
a length of each of the plurality of sub-bonding portions is set based on an elongation rate of the circuit board.

2. The display device of claim 1, wherein the length of the sub-bonding portion is calculated by a following equation:
C=B/A,
where A is an elongation rate of the sub-bonding portion per unit length,
B is a maximum elongation amount of the sub-bonding portion, and
C is the length of the sub-bonding portion.

3. The display device of claim 2, wherein B is set within 50% of a pitch of an outermost pad electrode of a plurality of pad electrodes that are disposed on the sub-bonding portion.

4. The display device of claim 1, wherein the circuit board includes:
an insulating layer;
a pad electrode disposed on the insulating layer;
a base layer disposed on the pad electrode;
an adhesive layer disposed on the base layer; and
a cover layer disposed on the adhesive layer.

5. The display device of claim 4, wherein the base layer includes the plurality of slits.

6. The display device of claim 5, wherein the base layer includes the plurality of slits in a bonding area of the circuit board.

7. The display device of claim 5, wherein the plurality of slits are arranged in the base layer along a first direction,
each of the plurality of slits extends in a second direction, and
the first direction and the second direction cross each other.

8. The display device of claim 5, wherein the base layer includes a polyimide.

9. The display device of claim 6, wherein the insulating layer includes a same material as the base layer.

10. The display device of claim 1, further comprising an anisotropic conductive film disposed between the display panel and the circuit board.

11. The display device of claim 5, wherein the insulating layer is disposed in a non-bonding area of the circuit board.

12. The display device of claim 5, wherein the pad electrode is disposed in a non-bonding area and a bonding area of the circuit board.

13. The display device of claim 5, wherein the base layer is disposed in a non-bonding area and a bonding area of the circuit board.

14. The display device of claim 5, wherein the adhesive layer is disposed in a non-bonding area and a bonding area of the circuit board.

15. The display device of claim 5, wherein the cover layer is disposed in a non-bonding area and a bonding area of the circuit board.

16. The display device of claim 5, wherein the pad electrode of the circuit board is connected to a pad electrode of the display panel.

17. The display device of claim 16, wherein the pad electrode of the circuit board is connected to the pad electrode of the display panel in a bonding area of the circuit board.

18. A method for fabricating a display device, comprising:
disposing an anisotropic conductive film on a substrate of a display panel;
disposing a circuit board on the anisotropic conductive film, wherein the circuit board includes a plurality of sub-bonding portions that are separated from each other by a plurality of slits;
disposing a heat conduction sheet on the circuit board;
disposing a heating/pressurizing header on the heat conduction sheet; and
connecting a pad electrode of the circuit board and a pad electrode that is disposed on the substrate to each other by pressurizing and heating the heat conduction sheet with the heating/pressurizing header,
wherein a length of each of the plurality of sub-bonding portions is set based on an elongation rate of the circuit board.

19. The method for fabricating a display device of claim 18, wherein the length of the sub-bonding portion is calculated by a following equation:
C=B/A,
where A is an elongation rate of the sub-bonding portion per unit length,
B is a maximum elongation amount of the sub-bonding portion, and
C is the length of the sub-bonding portion.

20. The method for fabricating a display device of claim 19, wherein B is set within 50% of a pitch of an outermost pad electrode of a plurality of pad electrodes that are disposed on the sub-bonding portion, wherein the plurality of pad electrodes includes the pad electrode of the circuit board.
